(19) United States
(12) Patent Application Publication
(10) Pub. No.: US 2026/0343902 A1
(43) Pub. Date: Oct. 29, 2026

(54) SEMICONDUCTOR DEVICE AND METHOD OF MANUFACTURING SEMICONDUCTOR DEVICE

(71) Applicant: SK Hynix Inc., Icheon-si (KR)

(72) Inventors: Won Jun LEE, Icheon-si (KR); Myoungsub KIM, Icheon-si (KR); Nam Kyun PARK, Icheon-si (KR); Jae Hyuk PARK, Icheon-si (KR); Sang Chul OH, Icheon-si (KR); Beom Seok LEE, Icheon-si (KR)

(21) Appl. No.: 19/445,172

(22) Filed: Jan. 9, 2026

(30) Foreign Application Priority Data
Apr. 24, 2025 (KR) 10-2025-0053979
Aug. 26, 2025 (KR) 10-2025-0119316

(51) Int. Cl. H10B 63/00

(52) U.S. Cl. CPC H10B 63/845; H10B 63/34

(57) ABSTRACT

A semiconductor device includes an electrode stack including conductive layers and insulating layers that are alternately stacked to form a step structure, a conductive plug extending through the electrode stack, memory cells disposed between the conductive layers and the conductive plug, an interlayer insulating layer disposed on the step structure, contact vias extending through the interlayer insulating layer and electrically connected to the conductive layers, respectively, and at least two of the contact vias having different widths, and barrier layers covering the contact vias, respectively, and at least two of the barrier layers having different thicknesses.

### CROSS-REFERENCE TO RELATED APPLICATIONS

This application claims priority under 35 U.S.C. §119 to Korean Patent Application No. 10-2025-0053979 filed on Apr. 24, 2025 and Korean Patent Application No. 10-2025-0119316 filed on Aug. 26, 2025, which are incorporated herein by reference in its entirety.

### BACKGROUND

### 1. Technical Field

Embodiments of the present disclosure relate to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include an electrode stack including conductive layers and insulating layers that are alternately stacked to form a step structure, a conductive plug extending through the electrode stack, memory cells disposed between the conductive layers and the conductive plug, an interlayer insulating layer disposed on the step structure, contact vias extending through the interlayer insulating layer and electrically connected to the conductive layers, respectively, and at least two of the contact vias having different widths, and barrier layers covering the contact vias, respectively, and at least two of the barrier layers having different thicknesses.

According to an embodiment of the present disclosure, a semiconductor device may include an electrode stack including a first conductive layer and a second conductive layer over the first conductive layer, the first conductive layer extending laterally beyond the second conductive layer to form a step structure, a conductive plug extending through the electrode stack, a selection transistor disposed under the electrode stack and connected to the conductive plug, a first memory cell disposed between the first conductive layer and the conductive plug and spaced apart from the selection transistor by a first distance, a second memory cell disposed between the second conductive layer and the conductive plug and spaced apart from the selection transistor by a second distance greater than the first distance, an interlayer insulating layer disposed on the step structure, a first contact structure extending through the interlayer insulating layer to be connected to the first conductive layer, and having a first resistance, and a second contact structure extending through the interlayer insulating layer to be connected to the second conductive layer, and having a second resistance less than the first resistance.

According to an embodiment of the present disclosure, a semiconductor device may include an electrode stack including conductive layers and insulating layers that are alternately stacked, a conductive plug extending through the electrode stack, a selection transistor disposed under the electrode stack and connected to the conductive plug, memory cells disposed between the conductive layers and the conductive plug, and contact structures connected to the conductive layers, respectively.

According to an embodiment of the present disclosure, a method of manufacturing a semiconductor device may include forming a sacrificial stack that includes first material layers and second material layers alternately stacked over a substrate so as to form a step structure exposing upper surfaces of the second material layers, forming an interlayer insulating layer on the step structure, forming memory cells in the sacrificial stack, forming a conductive plug extending through the memory cells, forming a slit extending through the sacrificial stack, forming openings by removing the second material layers through the slit, forming an electrode stack by forming conductive layers in the openings, respectively, forming contact holes that extend the interlayer insulating layer and expose the conductive layers, respectively, at least two of the contact holes having different heights, forming barrier layers in the contact holes, respectively, at least two of the barrier layers having different thicknesses, and forming contact vias in the barrier layers, respectively, at least two of the contact vias having different widths.

According to an embodiment of the present disclosure, a method of manufacturing a semiconductor device may include forming a selection transistor over a substrate, forming a sacrificial stack that includes first material layers and second material layers alternately stacked over the selection transistor, forming memory cells in the sacrificial stack, forming a conductive plug extending through the memory cells and connected to the selection transistor, forming a slit extending through the sacrificial stack, forming openings by removing the second material layers through the slit, forming an electrode stack by forming conductive layers in the openings, respectively, forming contact holes that expose the conductive layers, respectively, at least two of the contact holes having different heights, and forming contact structures in the contact holes, respectively.

### BRIEF DESCRIPTION OF THE DRAWINGS

FIGS. 1A, 1B and 1C, are diagrams illustrating a semiconductor device according to an embodiment of the present disclosure.

FIG. 2 is a drawing illustrating a semiconductor device according to an embodiment of the present disclosure.

FIGS. 3A, 3B, 4 and 5, are diagrams illustrating a semiconductor device according to an embodiment of the present disclosure.

FIGS. 6A, 6B, 6C, 6D, 6E, 6F, 6G, 6H, 6I and 6J, are diagrams illustrating a method of manufacturing a semiconductor device according to an embodiment of the present disclosure.

FIGS. 7A and 7B are diagrams illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and an improved characteristic.

According to embodiments of the present disclosure, a semiconductor device having a stable structure and improved reliability may be provided.

Hereinafter, some embodiments of the present disclosure are described with reference to the accompanying drawings.

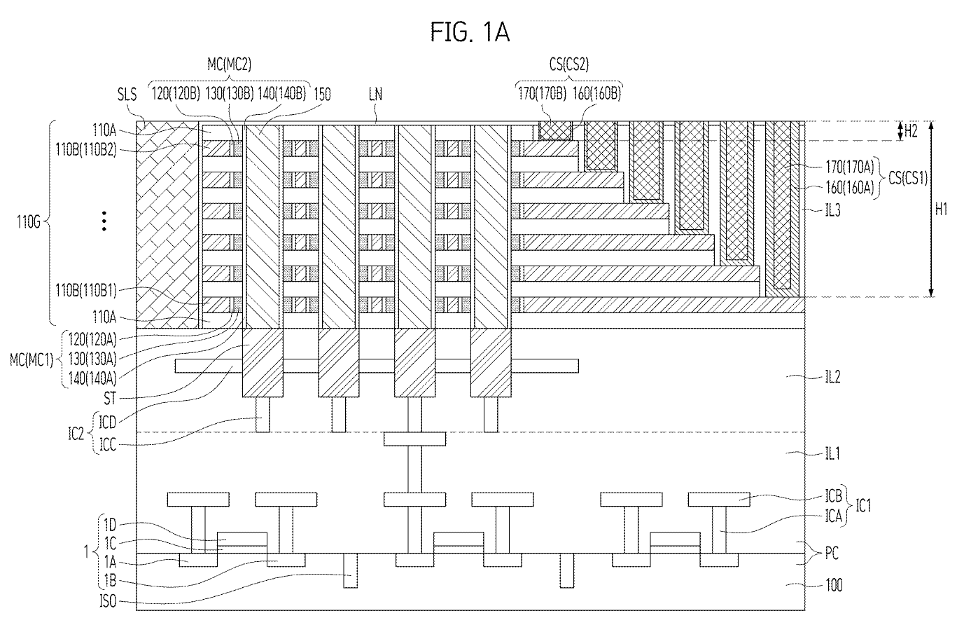

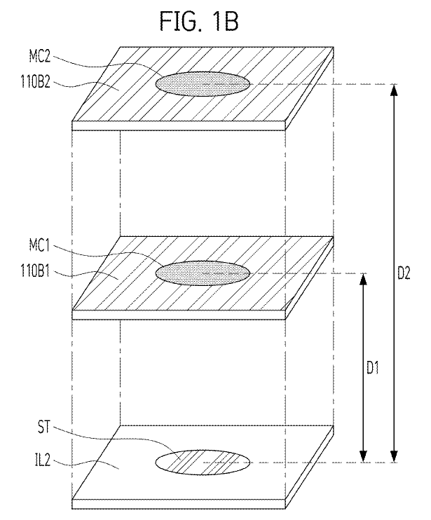

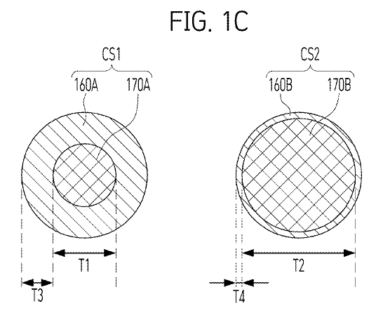

FIGS. 1A - 1C are diagrams illustrating a semiconductor device according to an embodiment of the present disclosure.

Referring to FIGS. 1A - 1C, the semiconductor device may include an electrode stack 110G, memory cells MC, conductive plugs 150, contact structures CS, and selection transistors ST. The semiconductor device may further include a substrate 100, a peripheral circuit PC, a first interconnection structure IC1, an element isolation layer ISO, a second interconnection structure IC2, a liner layer LN, a slit structure SLS, a first interlayer insulating layer IL1, a second interlayer insulating layer IL2, and a third interlayer insulating layer IL3.

The peripheral circuit PC may be disposed on the substrate 100. The peripheral circuit PC may include a transistor 1, a capacitor, and the like. The transistor 1 may include junctions 1A and 1B, a gate electrode 1D, and a gate insulating layer 1C. Here, the gate insulating layer 1C may be disposed between the gate electrode 1D and the substrate 100. The element isolation layer ISO may be disposed in the substrate 100, an active region may be formed by the element isolation layer ISO, and the transistor 1 may be disposed in the active region.

The first interconnection structure IC1 may be disposed on the peripheral circuit PC. The first interconnection structure IC1 may be disposed in the first interlayer insulating layer IL1. Here, the first interlayer insulating layer IL1 may be disposed on the substrate 100. The first interconnection structure IC1 may include first vias ICA and first lines ICB. At least one of the first vias ICA may be connected to the peripheral circuit PC. For example, at least one of the first vias ICA may be connected to the transistor 1. At least one of the first lines ICB may interconnect the first vias ICA. The first interconnection structure IC1 may include a conductive material such as tungsten. The first interlayer insulating layer IL1 may include an insulating material such as an oxide.

The second interconnection structure IC2 may be disposed on the first interconnection structure IC1. The second interconnection structure IC2 may be disposed in the second interlayer insulating layer IL2. Here, the second interlayer insulating layer IL2 may be disposed on the first interlayer insulating layer IL1. The second interconnection structure IC2 may include second lines ICC and a third line ICD. One of the second lines ICC may be connected to the first line ICB. For reference, a connection via (not shown) may be disposed between the first line ICB and the second lines ICC, and the first line ICB and the second line ICC may be connected through the connection via. The third line ICD may be electrically connected to the second lines ICC through the selection transistors ST. Here, the second lines ICC may be a first bit line used as an input/output path for data for the memory cells MC, and the third line ICD may be a word line for controlling the selection transistors ST. The second interconnection structure IC2 may include a conductive material such as tungsten. The second interlayer insulating layer IL2 may include an insulating material such as an oxide.

The selection transistors ST may be disposed on (or over) the first interconnection structure IC1. The selection transistors ST may extend through the third line ICD and may be connected to the second line ICC. The selection transistors ST may be configured to correspond to each of the memory cells MC disposed in a memory array. For example, each of the selection transistors ST may be configured to correspond to a memory string including a plurality of memory cells MC. The selection transistor ST may perform a switching function selectively activating or deactivating the memory string. For example, the selection transistors may be switched to a turn-on or turn-off state in response to a selection signal applied from the word line, and may open or block a current path for memory cells connected to a specific selection transistor, thereby allowing access to only a desired memory cell. Each of the selection transistors ST may include a gate electrode, a source/drain region, a gate insulating layer, and the like. Hereinafter, embodiments will be described based on a memory string corresponding to one selection transistor ST and a plurality of memory cells MC included in the memory string.

The electrode stack 110G may be disposed on the selection transistors ST. In other words, the selection transistors ST may be disposed under the electrode stack 110G. The electrode stack 110G may include insulating layers 110A and conductive layers 110B alternately stacked, and may include a step structure. For example, the electrode stack 110G may include insulating layers 110A and conductive layers 110B that are alternately stacked to form a step structure. Upper surfaces of the conductive layers 110B may be exposed through the step structure. Here, the upper surfaces (e.g., portions of the upper surfaces) and side surfaces of the conductive layers 110B exposed through the step structure may be covered through the third interlayer insulating layer IL3. The third interlayer insulating layer IL3 may be disposed on the step structure. The conductive layers 110B may be a word plate for controlling the memory cells MC. The third interlayer insulating layer IL3 may include an insulating material such as an oxide.

The memory cells MC may be disposed between the conductive layers 110B and the conductive plug 150. For example, each of the memory cells MC may be disposed between a corresponding (e.g., disposed in) one of the conductive layers 110B and a corresponding (e.g., contacting) portion of the conductive plug 150. Here, the conductive plugs 150 may extend through the electrode stack 110G. In addition, the conductive plugs 150 may be connected to the second lines ICC, respectively, by extending through the electrode stack 110G.

Each of the memory cells MC may include a first electrode pattern 120, a variable resistance pattern 130, and a second electrode pattern 140. For example, the memory cells MC may include the first electrode patterns 120 each disposed at a level corresponding to the conductive layers 110B, the second electrode pattern 140 covering a sidewall of the conductive plug 150, and the variable resistance patterns 130 disposed between the first electrode patterns 120 and the second electrode pattern 140. Specifically, each of the memory cells MC may include a first electrode pattern 120 disposed at substantially the same level as a corresponding one of the conductive layers 110B, a second electrode pattern 140 covering a sidewall of the conductive plug 150, and a variable resistance pattern 130 disposed between the first electrode pattern 120 and the second electrode pattern 140. For example, when an upper surface of the first electrode pattern 120 and an upper surface of the corresponding conductive layer 110B are positioned at first and second levels from an upper surface of the substrate 100, respectively, a difference between the first and second levels may be not greater than 5%, 3%, or 1% of a thickness of the conductive layer 110B.

At least one of the first electrode pattern 120 or the second electrode pattern 140 may include polysilicon, tungsten (W), tungsten nitride (WNx), tungsten silicide (WSix), titanium (Ti), titanium nitride (TiNx), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbon nitride (SiCN), copper (Cu), zinc (Zn), nickel (Ni), cobalt (Co), lead (Pd), platinum (Pt), molybdenum (Mo), ruthenium (Ru), or the like. Throughout the specification and claims, a list of items prefaced by a phrase such as “at least one of” or “one or more of” or “one or both of” indicates an inclusive list. For example, a list of “at least one of A or B” and a list of “one or both of A and B” each indicate A, or B, or AB (i.e., A and B).

The variable resistance pattern 130 may include a resistive material, and may have a characteristic of reversibly transitioning between different resistance states according to an applied voltage or current.

The variable resistance pattern 130 may include a metal oxide (e.g., transition metal oxide), or may include a metal oxide such as a perovskite material. Therefore, data may be stored in the memory cell MC by generating or eliminating an electrical path in the variable resistance pattern 130.

The variable resistance pattern 130 may have an MTJ structure, and may include a magnetization fix layer, a magnetization free layer, and a tunnel barrier layer interposed therebetween. For example, the magnetization fix layer and the magnetization free layer may include a magnetic material, and the tunnel barrier layer may include an oxide such as magnesium (Mg), aluminum (Al), zinc (Zn), or titanium (Ti). Here, a magnetization direction of the magnetization free layer may be changed by spin torque of electrons in an applied current. Therefore, data may be stored in the memory cell MC according to a magnetization direction change of the magnetization free layer for a magnetization direction of the magnetization fix layer.

The variable resistance pattern 130 may include a phase change material, and may include a chalcogenide. The variable resistance pattern 130 may include a chalcogenide glass, a chalcogenide alloy, etc. The variable resistance pattern 130 may include silicon (Si), germanium (Ge), antimony (Sb), tellurium (Te), bismuth (Bi), indium (In), tin (Sn), selenium (Se), or the like, or may include a combination thereof. The variable resistance pattern 130 may be Ge-Sb-Te (GST), and may be Ge₂Sb₂Te₅, Ge₂Sb₂Te₇, Ge₁Sb₂Te₄, Ge₁Sb₄Te₇, or the like. A phase of the variable resistance pattern 130 may change according to a program operation. For example, the variable resistance pattern 130 may have a low-resistance crystalline state by a set operation. In addition, the variable resistance pattern 130 may have a high-resistance amorphous state by a reset operation. Therefore, data may be stored in the memory cell MC by using a resistance difference according to the phase of the variable resistance pattern 130.

The variable resistance pattern 130 may include a variable resistance material of which a resistance changes without a phase change, and may include a chalcogenide-based material. The variable resistance pattern 130 may include germanium (Ge), antimony (Sb), tellurium (Te), arsenic (As), selenium (Se), silicon (Si), indium (In), tin (Sn), sulfur (S), gallium (Ga), or the like, or may include a combination thereof. The variable resistance pattern 130 may include a chalcogenide maintaining an amorphous state during the program operation. The variable resistance pattern 130 may have an amorphous state, and may not change to a crystalline state during the program operation. Therefore, a threshold voltage of the memory cell MC may change according to a program voltage applied to the memory cell MC, and the memory cell may be programmed to at least two states. For example, when a negative program voltage is applied to the memory cell MC, the memory cell may have a relatively high threshold voltage. In addition, when a positive program voltage is applied to the memory cell MC, the memory cell may have a relatively low threshold voltage. Therefore, data may be stored in the memory cell MC by using a threshold voltage difference of the memory cells MC.

Meanwhile, the conductive plugs 150 may be a second bit line used as a data input/output path for the memory cells MC. In other words, the conductive plugs 150 and the second line ICC may be electrically connected, and the first and second bit lines may be used as a single bit line. In summary, the third line ICD may be the word line, the conductive layers 110B may be the word plate, and the conductive plugs 150 and the second lines ICC may be the bit line. For example, by applying a voltage to the word line, a selection transistor ST connected to the corresponding word line may be turned on, and thus a current may flow between the memory cells MC corresponding to the selection transistor ST and the bit line. In addition, by applying a voltage to the word plate, a memory cell MC disposed at a level corresponding to the word plate may be selected. When the selection transistor ST is turned on and the memory cell MC is selected, data of the selected memory cell MC may be read or written through the bit line. Here, the voltage may be applied to the word plate through the contact structures CS.

The contact structures CS may extend through the third interlayer insulating layer IL3, and may be connected to the conductive layers 110B, respectively. The contact structures CS may be used as a path for applying a voltage to the conductive layers 110B. Heights of the contact structures CS may be different from each other. Widths of the contact structures CS may be substantially the same. For example, a difference between widths of a pair of the contact structures CS may be not greater than 5%, 3%, or 1% of an average of the widths.

Each of the contact structures CS may include a barrier layer 160 and a contact via 170. The contact via 170 may extend through the third interlayer insulating layer IL3 to be electrically connected to the conductive layers 110B, respectively. Here, the contact vias 170 may have different widths. The barrier layers 160 may cover the contact vias 170, respectively. For example, the barrier layer 160 may cover one or more side surfaces and a lower surface of the contact via 170. Here, the barrier layers 160 may have different thicknesses.

The contact vias 170 may have a first resistivity, and the barrier layer 160 may have a second resistivity different from the first resistivity. For example, the second resistivity may be greater than the first resistivity. The contact vias 170 may include a metal material, and the barrier layers 160 may include a metal nitride. For example, the contact vias 170 may include tungsten, and the barrier layers 160 may include tungsten nitride.

The memory cells MC may include a first memory cell MC1 and a second memory cell MC2 on (or over) the first memory cell MC1. For example, the memory cells MC may include the first memory cell MC1 adjacent to the selection transistor ST and the second memory cell MC2 spaced apart relatively farther from the selection transistor ST than the first memory cell MC1. The conductive layers 110B may include a first conductive layer 110B1 connected to the first memory cell MC1 and a second conductive layer 110B2 connected to the second memory cell MC2.

The contact structures CS may include a first contact structure CS1 connected to the first conductive layer 110B1 and a second contact structure CS2 connected to the second conductive layer 110B2. Here, the first contact structure CS1 may have a first height H1, and the second contact structure CS2 may have a second height H2 less than the first height H1. The first contact structure CS1 may include a first contact via 170A and a first barrier layer 160A. The second contact structure CS2 may include a second contact via 170B and a second barrier layer 160B. The contact vias 170 may include the first contact via 170A electrically connected to the first conductive layer 110B1 and the second contact via 170B electrically connected to the second conductive layer 110B2. The barrier layers 160 may include the first barrier layer 160A covering the first contact via 170A and the second barrier layer 160B covering the second contact via 170B.

The first memory cell MC1 may be electrically connected from the selection transistor ST to the first contact structure CS1 through the conductive plug (e.g., a first portion of the conductive plug) 150 and the first conductive layer 110B1. The second memory cell MC2 may be electrically connected from the selection transistor ST to the second contact structure CS2 through the conductive plug (e.g., a second portion of the conductive plug) 150 and the second conductive layer 110B2. Here, the first memory cell MC1 may have a first distance D1 from the selection transistor ST, and the second memory cell MC2 may have a second distance D2 greater than the first distance D1 from the selection transistor ST. For example, the first memory cell (e.g., an upper surface of the first memory cell, a center plane located between upper and lower surfaces of the first memory cell, etc.) MC1 is spaced apart from the selection transistor (e.g., an upper surface of the selection transistor) ST by a first distance, and the second memory cell (e.g., an upper surface of the second memory cell, a center plane located between upper and lower surfaces of the second memory cell, etc.) MC2 is spaced apart from the selection transistor ST by a second distance greater than the first distance. A length of the conductive plug 150 from the selection transistor ST to the first memory cell MC1 may be substantially the same as the first distance D1, and a length of the conductive plug 150 from the selection transistor ST to the second memory cell MC2 may be substantially the same as the second distance D2.

By applying a voltage to the word line, a selection transistor connected to the corresponding word line may be turned on. At this time, a current may flow to a memory cell corresponding to the selection transistor through the bit line. In addition, by applying a voltage to the word plate through the contact structure, a memory cell disposed at a level corresponding to the word plate may be selected. Here, when a distance between the memory cell and the selection transistor is relatively short, that is, when a length of a portion of the bit line connecting the memory cell and the selection transistor is relatively short, a resistance of the connecting portion of the bit line may be relatively small. In this case, a high spike current may momentarily flow through the memory cell, and this may cause electrical stress in the memory cell and damage the memory cell.

In a case of the first memory cell MC1 disposed relatively close to the selection transistor ST compared to the second memory cell MC2, a spike current may occur, and thus the first memory cell MC1 may be damaged. In other words, because a length of a first portion of the conductive plug 150 electrically connecting the first memory cell MC1 and the selection transistor ST is shorter than that of a second portion of the conductive plug 150 electrically connecting the second memory cell MC2 and the selection transistor ST, a resistance of the first portion of the conductive plug 150 may be relatively small, and thus the first memory cell MC1 connected to the first portion may be damaged. Therefore, in order to prevent or minimize damage to the first memory cell MC1, the relatively small resistance of the first portion of the conductive plug 150 connecting the first memory cell MC1 and the selection transistor ST may be compensated for.

The first contact structure CS1 may have a first resistance, and the second contact structure CS2 may have a second resistance less than the first resistance. For example, the first contact structure CS1 may have a first height H1, and the second contact structure CS2 may have a second height H2 less than the first height H1. In addition, the first contact via 170A may have a first width T1, and the second contact via 170B may have a second width T2 greater than the first width T1. The first barrier layer 160A may have a third thickness T3, and the second barrier layer 160B may have a fourth thickness T4 less than the third thickness T3. Here, the first and second barrier layers 160A and 160B may have a resistivity greater than a resistivity of the first and second contact vias 170A and 170B.

In other words, the first contact structure CS1 may have the first height H1 greater than the second height H2 of the second contact structure CS2. In addition, the first thickness T1 of the first contact via 170A may be less than the second thickness T2 of the second contact via 170B. In addition, the third thickness T3 of the first barrier layer 160A may be greater than the fourth thickness T4 of the second barrier layer 160B.

Because the first contact structure CS1 has the height greater than the height of the second contact structure CS2, a resistance of the first contact structure CS1 may be relatively large. In addition, because the first contact structure CS1 includes the first contact via 170A of a relatively small width and the first barrier layer 160A of a relatively large thickness, a resistance of the first contact structure CS1 may be greater than a resistance of the second contact structure CS2 including the second contact via 170B of a relatively large width and the second barrier layer 160B of a relatively small thickness.

Accordingly, the first contact structure CS1 may have the resistance higher than the resistance of the second contact structure CS2. In this case, the first contact structure CS1 may compensate for the relatively small resistance of the first portion of the conductive plug 150 connecting the first memory cell MC1 and the selection transistor ST. In other words, a sum of the resistance of the first portion of the conductive plug 150 connecting the first memory cell MC1 and the selection transistor ST and the resistance of the first contact structure CS1 may be substantially equal to or similar to a sum of the resistance of the second portion of the conductive plug 150 connecting the second memory cell MC2 and the selection transistor ST and the resistance of the second contact structure CS2. Therefore, by forming the first contact structure CS1 to have a relatively large resistance, damage to the first memory cell MC1 due to the spike current may be prevented or minimized.

For reference, the above descriptions of the present disclosure on the first and second memory cells MC1 and MC2 may also be applied to other memory cells MC sequentially spaced apart from the selection transistor ST. For example, also with respect to memory cells MC disposed between the first memory cell MC1 and the second memory cell MC2, the contact structures CS may be formed by adjusting a ratio of the contact vias 170 and the barrier layers 160 so that the a sum of the resistance of the conductive plugs 150 connecting the memory cells MC and the selection transistors ST and the resistance of the contact structures CS connected to the conductive layers 110B corresponding to the memory cells MC is substantially the same.

The slit structure SLS may extend through the electrode stack 110G. The slit structure SLS may be formed by forming an insulating material, a semiconductor material, or a conductive material in a slit used in a process of manufacturing the semiconductor device. Therefore, the slit structure SLS may include at least one of an insulating material, a semiconductor material, or a conductive material.

The liner layer LN may extend along an upper surface of the electrode stack 110G and between the slit structure SLS and the electrode stack 110G. The liner layer LN may cover an upper surface of the second electrode pattern 140 and an upper surface of the conductive plug 150 in the process of manufacturing the semiconductor device. The liner layer LN may include an insulating material such as an oxide or a nitride.

For reference, although this drawing illustrates a case where the electrode stack 110G includes a step structure, the electrode stack 110G may not include a step structure. In this case, the third interlayer insulating layer IL3 may not exist. The contact structures CS may extend through the electrode stack 110G to be connected to the respective conductive layers 110B. At this time, insulating spacers covering a sidewall of the contact structure CS may be disposed to prevent remaining conductive layers 110B except for the conductive layer 110B connected to the contact structure CS from being electrically connected to the contact structure CS.

According to the structure described above, the first contact structure CS1 may have the height greater than the height of the second contact structure CS2. In addition, the first contact structure CS1 may include the first contact via 170A having a width less than a width of the second contact via 170B of the second contact structure CS2, and may include the first barrier layer 160A having a thickness greater than a thickness of the second barrier layer 160B of the second contact structure CS2. Each of the first and second contact vias 170A and 170B may have a resistivity less than that of each of the first and second barrier layers 160A and 160B. Therefore, the first resistance of the first contact structure CS1 may be greater than the second resistance of the second contact structure CS2.

In other words, the first resistance of the first contact structure CS1 corresponding to the first memory cell MC1 disposed adjacent to the selection transistor ST may be greater than the second resistance of the second contact structure CS2 corresponding to the second memory cell MC2 disposed relatively farther from the selection transistor ST. Therefore, the first contact structure CS1 may prevent the first memory cell MC1 from being damaged due to a relatively small distance between the first memory cell MC1 and the selection transistor ST.

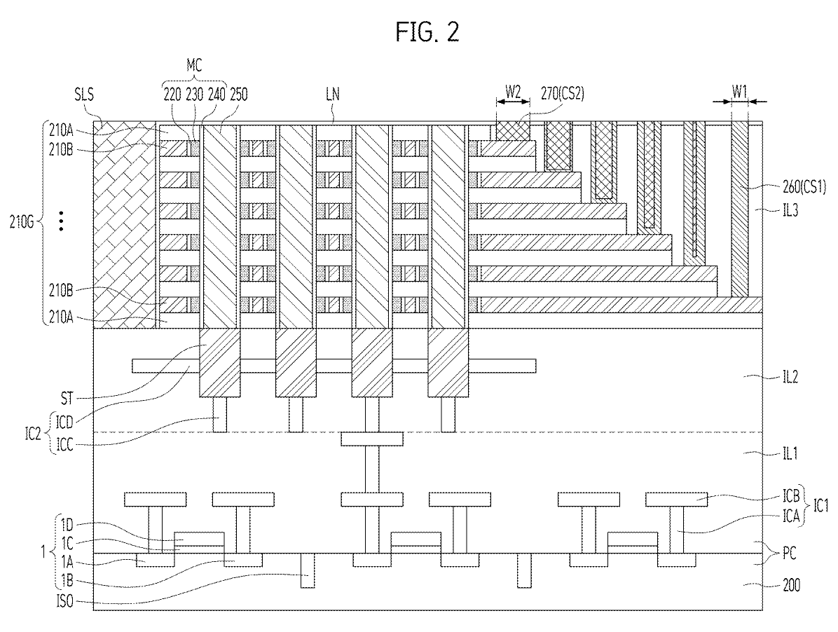

FIG. 2 is a drawing illustrating a semiconductor device according to an embodiment of the present disclosure. Hereinafter, a content that overlaps the content described above may be omitted for the interest of brevity.

Referring to FIG. 2, the semiconductor device may include an electrode stack 210G, memory cells MC, conductive plugs 250, contact structures CS, and selection transistors ST. The semiconductor device may further include a substrate 200, a peripheral circuit PC, a first interconnection structure IC1, an element isolation layer ISO, a second interconnection structure IC2, a liner layer LN, a slit structure SLS, a first interlayer insulating layer IL1, a second interlayer insulating layer IL2, and a third interlayer insulating layer IL3.

The peripheral circuit PC may be disposed on the substrate 200. The peripheral circuit PC may include a transistor 1, a capacitor, and the like. The transistor 1 may include junctions 1A and 1B, a gate electrode 1D, and a gate insulating layer 1C. The element isolation layer ISO may be disposed in the substrate 200, and an active region may be formed by the element isolation layer ISO, and the transistor 1 may be disposed in the active region.

The first interconnection structure IC1 may be disposed on the peripheral circuit PC. The first interconnection structure IC1 may be disposed in the first interlayer insulating layer IL1. Here, the first interlayer insulating layer IL1 may be disposed on the substrate 200. The first interconnection structure IC1 may include first vias ICA and first lines ICB.

The second interconnection structure IC2 may be disposed on the first interconnection structure IC1. The second interconnection structure IC2 may be disposed in the second interlayer insulating layer IL2. Here, the second interlayer insulating layer IL2 may be disposed on the first interlayer insulating layer IL1. The second interconnection structure IC2 may include second lines ICC and a third line ICD.

The selection transistors ST may be disposed on the first interconnection structure IC1. The selection transistors ST may extend through the third line ICD and may be connected to the second line ICC. The selection transistors ST may be configured to correspond to each of the memory cells MC disposed in a memory array. The selection transistor ST may perform a switching function selectively activating or deactivating a memory string. Each of the selection transistors ST may include a gate electrode, a source/drain region, a gate insulating layer, and the like.

The electrode stack 210G may be disposed on the selection transistors ST. In other words, the selection transistors ST may be disposed under the electrode stack 210G. The electrode stack 210G may include insulating layers 210A and conductive layers 210B alternately stacked, and may include a step structure. For example, the electrode stack 210G may include insulating layers 210A and conductive layers 210B that are alternately stacked to form a step structure. Here, upper surfaces of the conductive layers 210B exposed through the step structure may be covered through the third interlayer insulating layer IL3. The third interlayer insulating layer IL3 may be disposed on the step structure.

The memory cells MC may be disposed between the conductive layers 210B and the conductive plug 250. For example, each of the memory cells MC may be disposed between a corresponding (e.g., disposed in) one of the conductive layers 210B and a corresponding (e.g., contacting) portion of the conductive plug 250. Here, the conductive plugs 250 may extend through the electrode stack 210G. In addition, the conductive plugs 250 may extend through the electrode stack 210G to be connected to the second lines ICC, respectively.

Each of the memory cells may include a first electrode pattern 220, a variable resistance pattern 230, and a second electrode pattern 240. For example, the memory cells MC may include the first electrode patterns 220 disposed at a level corresponding to the conductive layers 210B, the second electrode pattern 240 covering a sidewall of the conductive plugs 250, and the variable resistance patterns 230 disposed between the first electrode patterns 220 and the second electrode pattern 240.

The contact structures may extend through the third interlayer insulating layer IL3, and may be connected to the conductive layers 210B, respectively. Each of the contact structures may include at least one of a contact via 270 or a barrier layer 260. As an example, the first contact structure CS1 may consist of the barrier layer 260. As another example, the second contact structure CS2 may consist of the contact via 270. Heights of the contact structures may be different from each other.

The contact vias 270 may extend through the third interlayer insulating layer IL3 to be electrically connected to the conductive layers 210B, respectively. Here, the contact vias 270 may have different widths. The barrier layer 260 may cover the contact vias 270. For example, the barrier layer 260 may cover one or more side surfaces and a lower surface of the contact via 270. Here, the barrier layers 260 may have different thicknesses.

The contact vias 270 may have a first resistivity, and the barrier layer 260 may have the first resistivity and a second resistivity greater than the first resistivity. The contact vias 270 may include a metal material, and the barrier layers 260 may include a metal nitride. For example, the contact vias 270 may include tungsten, and the barrier layers 260 may include tungsten nitride.

The first contact structure CS1 may have a first resistance, and the second contact structure CS2 may have a second resistance less than the first resistance. The first contact structure CS1 may have a height greater than a height of the second contact structure CS2. In addition, the first contact structure CS1 may have a first width W1, and the second contact structure CS2 may have a second width W2 different from the first width W1. Here, the first width W1 may be less than the second width W2.

In other words, the first contact structure CS1 may have the height greater than the height of the second contact structure CS2, and the first contact structure CS1 may have the first width W1 less than the second width W2 of the second contact structure CS2. In addition, the first contact structure CS1 may include the barrier layer 260 of which the resistivity is relatively great, and the second contact structure CS2 may include the contact via 270 of which the resistivity is relatively small. Therefore, the resistance of the first contact structure CS1 may be relatively greater than the resistance of the second contact structure CS2.

Accordingly, the first contact structure CS1 may have the resistance greater than the resistance of the second contact structure CS2. In this case, the first contact structure CS1 may prevent or minimize damage to the memory cell MC disposed relatively adjacent to the selection transistor ST due to a spike current.

For reference, although this drawing illustrates a case where the first and second widths W1 and W2 of the first and second contact structures CS1 and CS2 are constant from an upper surface to a lower surface, the first and second contact structures CS1 and CS2 may have a cross-section of a taper shape. In this case, the widths of the first and second contact structures CS1 and CS2 may be decreased from the upper surface to the lower surface.

In addition, although this drawing illustrates a case where the first contact structure CS1 does not include the contact via 270 and the second contact structure CS2 does not include the barrier layer 260, embodiments of the present disclosure are not limited thereto. For example, the first contact structure CS1 may include a contact via(not shown) in the barrier layer 260, and the second contact structure CS2 may include a barrier layer (not shown) covering the contact via 270.

The slit structure SLS may extend through the electrode stack 210G. The slit structure SLS may include at least one of an insulating material, a semiconductor material, or a conductive material.

The liner layer LN may extend along an upper surface of the electrode stack 210G and between the slit structure SLS and the electrode stack 210G. The liner layer LN may include an insulating material such as an oxide or a nitride.

According to the structure described above, the first contact structure CS1 may have the first width W1 relatively less than the second width W2 of the second contact structure CS2. In addition, the first contact structure CS1 may have the height relatively greater than the height of the second contact structure CS2. In addition, the first contact structure CS1 may consist of the barrier layer 260 of which the resistivity is greater than the resistivity of the contact via 270, and the second contact structure CS2 may consist of the contact via 270. In this case, the first contact structure CS1 may have the resistance greater than the resistance of the second contact structure CS2, and may prevent damage to the memory cell MC disposed adjacent to the selection transistor ST.

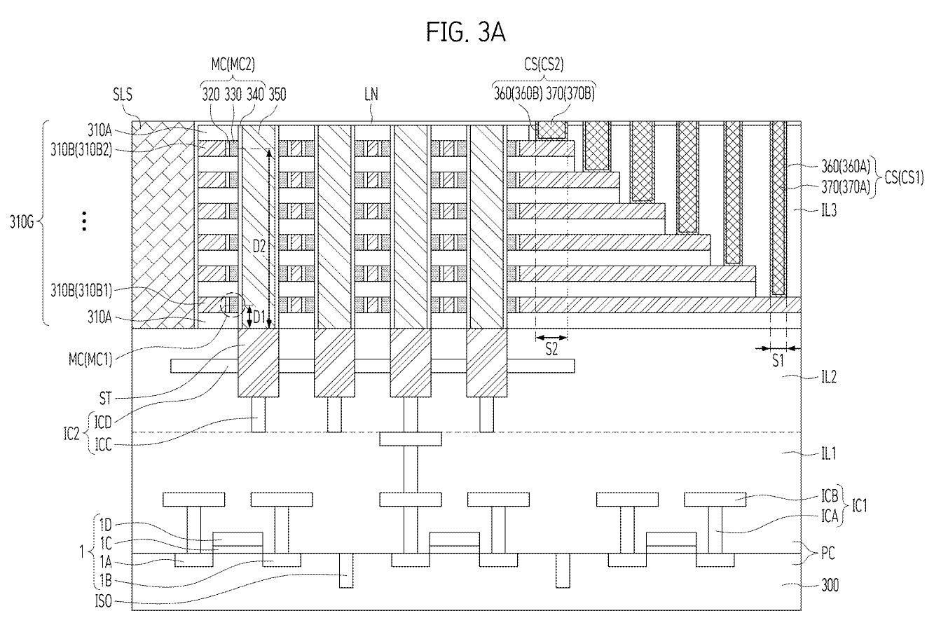

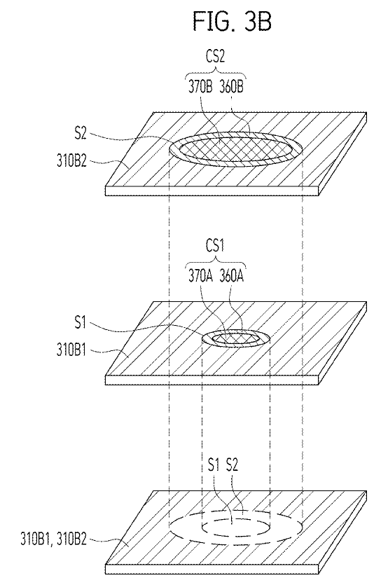

FIGS. 3A, 3B, 4 and 5, are diagrams illustrating a semiconductor device according to embodiments of the present disclosure. Hereinafter, a content that overlaps the content described above is may be omitted for the interest of brevity.

Referring to FIGS. 3A, 3B, 4 and 5, the semiconductor device may include an electrode stack 310G, 410G, or 510G, memory cells MC, conductive plugs 350, 450, or 550, contact structures CS, and selection transistors ST. The semiconductor device may further include a substrate 300, 400, or 500, a peripheral circuit PC, a first interconnection structure IC1, an element isolation layer ISO, a second interconnection structure IC2, a liner layer LN, a slit structure SLS, a first interlayer insulating layer IL1, a second interlayer insulating layer IL2, and a third interlayer insulating layer IL3.

The peripheral circuit PC may be disposed on the substrate 300, 400, or 500. The peripheral circuit PC may include a transistor 1, a capacitor, and the like. The transistor 1 may include junctions 1A and 1B, a gate electrode 1D, and a gate insulating layer 1C. The element isolation layer ISO may be disposed in the substrate 300, 400, or 500, an active region may be formed by the element isolation layer ISO, and the transistor 1 may be disposed in the active region.

The first interconnection structure IC1 may be disposed on the peripheral circuit PC. The first interconnection structure IC1 may be disposed in the first interlayer insulating layer IL1. Here, the first interlayer insulating layer IL1 may be disposed on the substrate 300, 400, or 500. The first interconnection structure IC1 may include first vias ICA and first lines ICB.

The second interconnection structure IC2 may be disposed on the first interconnection structure IC1. The second interconnection structure IC2 may be disposed in the second interlayer insulating layer IL2. Here, the second interlayer insulating layer IL2 may be disposed on the first interlayer insulating layer IL1. The second interconnection structure IC2 may include second lines ICC and a third line ICD.

The selection transistors ST may be disposed on the first interconnection structure IC1. The selection transistors ST may extend through the third line ICD and may be connected to the second line ICC. The selection transistors ST may be configured to correspond to each of the memory cells MC disposed in a memory array. The selection transistors ST may perform a switching function selectively activating or deactivating a memory string. Each of the selection transistors ST may include a gate electrode, a source/drain region, a gate insulating layer, and the like.

The electrode stack 310G, 410G, or 510G may be disposed on the selection transistors ST. In other words, the selection transistors ST may be disposed under the electrode stacks 310G, 410G, or 510G. The electrode stack 310G, 410G, or 510G may include insulating layers 310A, 410A, or 510A and conductive layers 310B, 410B, or 510B alternately stacked, and may include a step structure. Here, upper surfaces of the conductive layers 310B, 410B, or 510B exposed through the step structure may be covered through the third interlayer insulating layer IL3. The third interlayer insulating layer IL3 may be disposed on the step structure.

The memory cells MC may be disposed between the conductive layers 310B, 410B, or 510B and the conductive plugs 350, 450, or 550. Here, the conductive plugs 350, 450, or 550 may extend through the electrode stack 310G, 410G, or 510G. In addition, the conductive plugs 350, 450, or 550 may extend through the electrode stack 310G, 410G, or 510G to be connected to second lines ICC, respectively.

Each of the memory cells MC may include a first electrode pattern 320, 420, or 520, a variable resistance pattern 330, 430, or 530, and a second electrode pattern 340, 440, or 540. For example, the memory cells MC may include the first electrode patterns 320, 420, or 520 each disposed at a level corresponding to the conductive layers 310B, 410B, or 510B, the second electrode patterns 340, 440, or 540 covering sidewalls of the conductive plugs 350, 450, or 550, and the variable resistance patterns 330, 430, or 530 disposed between the first electrode patterns 320, 420, or 520 and the second electrode patterns 340, 440, or 540.

The slit structure SLS may extend through the electrode stack 310G, 410G, or 510G. The slit structure SLS may include at least one of an insulating material, a semiconductor material, or a conductive material.

The liner layer LN may extend along an upper surface of the electrode stack 310G, 410G, or 510G and between the slit structure SLS and the electrode stack 310G, 410G, or 510G. The liner layer LN may include an insulating material such as an oxide or a nitride.

The contact structures CS may extend through the third interlayer insulating layer IL3, and may be connected to the conductive layers 310B, 410B, or 510B, respectively. Heights of the contact structures CS may be different from each other. Each of the contact structures CS may include at least one of a contact via 370, 470, or 570 or a barrier layer 360, 460, or 560.

The contact vias 370, 470, or 570 may extend through the third interlayer insulating layer IL3 to be electrically connected to the conductive layers 310B, 410B, or 510B, respectively. The barrier layer 360, 460, or 560 may cover the contact via 370, 470, or 570. For example, the barrier layer 360, 460, or 560 may cover one or more side surfaces and a lower surface of the contact via 370, 470, or 570. Here, the barrier layers 360, 460, and 560 may have substantially the same thickness.

The contact vias 370, 470, and 570 may have a first resistivity, and the barrier layer 360, 460, and 560 may have the first resistivity and a second resistivity greater than the first resistivity. The contact vias 370, 470, and 570 may include a metal material, and the barrier layers 360, 460, and 560 may include a metal nitride. For example, the contact vias 370, 470, and 570 may include tungsten, and the barrier layers 360, 460, and 560 may include tungsten nitride.

Referring to FIGS. 3A and 3B, the memory cells MC may include a first memory cell MC1 and a second memory cell MC2 on (or over) the first memory cell MC1. For example, the memory cells MC may include the first memory cell MC1 adjacent to the selection transistor ST and the second memory cell MC2 spaced apart relatively farther from the selection transistor ST than the first memory cell MC1. The conductive layers 310B may include a first conductive layer 310B1 connected to the first memory cell MC1 and a second conductive layer 310B2 connected to the second memory cell MC2.

The first memory cell MC1 may be electrically connected from the selection transistor ST to the first contact structure CS1 through the conductive plug (e.g., a first portion of the conductive plug) 350 and the first conductive layer 310B1. The second memory cell MC2 may be electrically connected from the selection transistor ST to the second contact structure CS2 through the conductive plug (e.g., a second portion of the conductive plug) 350 and the second conductive layer 310B2.

The first memory cell MC1 may have a first distance D1 from the selection transistor ST, and the second memory cell MC2 may have a second distance D2 greater than the first distance D1 from the selection transistor ST. For example, the first memory cell (e.g., an upper surface of the first memory cell, a center plane located between upper and lower surfaces of the first memory cell, etc.) MC1 is spaced apart from the selection transistor (e.g., an upper surface of the selection transistor) ST by a first distance, and the second memory cell (e.g., an upper surface of the second memory cell, a center plane located between upper and lower surfaces of the second memory cell, etc.) MC2 is spaced apart from the selection transistor ST by a second distance greater than the first distance. A length of the conductive plug 350 from the selection transistor ST to the first memory cell MC1 may be substantially the same as the first distance D1, and a length of the conductive plug 350 from the selection transistor ST to the second memory cell MC2 may be substantially the same as the second distance D2.

A cross-sectional area where the contact structure CS contacts the conductive layer 310B is decreased, a resistance of the contact structure CS may increase. In addition, a height of the contact structure CS is increased, the resistance of the contact structure CS may increase.

The first contact structure CS1 may contact the first conductive layer 310B1 at an interface having a first cross-sectional area S1, and the second contact structure CS2 may contact the second conductive layer 310B2 at an interface having a second cross-sectional area S2 different from that of the second conductive layer 310B2. Here, the first cross-sectional area S1 may be less than the second cross-sectional area S2. In addition, the first contact structure CS1 may have a height greater than the height of the second contact structure CS2.

In other words, the first contact structure CS1 may have the height greater than the height of the second contact structure CS2, and the first contact structure CS1 may contact the conductive layer 310B at an interface having the cross-sectional area less than the cross-sectional area of the second contact structure CS2. Therefore, the second contact structure CS2 may have a second resistance, and the first contact structure CS1 may have a first resistance greater than the second resistance. Here, thicknesses of the first barrier layer 360A of the first contact structure CS1 and the second barrier layer 360B of the second contact structure CS2 may be substantially the same. For example, when the first barrier layer 360A has a first thickness and the second barrier layer 360B has a second thickness, a difference between the first and second thicknesses may be not greater than 5%, 3%, or 1% of an average of the first and second thicknesses.

According to an embodiment of the present disclosure, the first contact structure CS1 may have the resistance greater than the resistance of the second contact structure CS2. In this case, the first contact structure CS1 may prevent or minimize damage to the memory cell MC disposed relatively adjacent to the selection transistor ST due to a spike current.

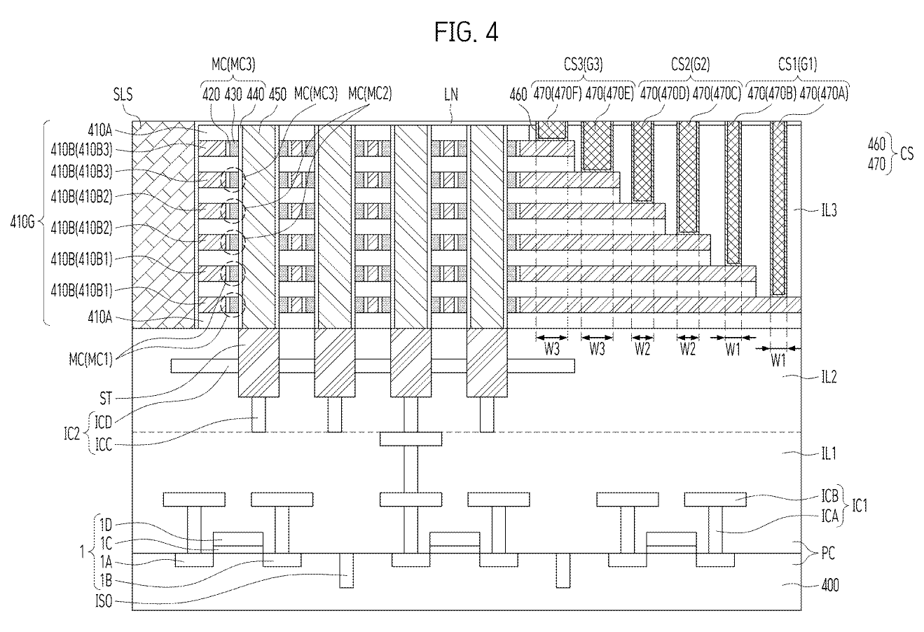

Referring to FIG. 4, the memory cells MC may include first memory cells MC1 adjacent to the selection transistor ST, second memory cells MC2 spaced apart relatively farther from the selection transistor ST than the first memory cells MC1, and third memory cells MC3 spaced apart relatively farther from the selection transistor ST than the second memory cells MC2. Here, in consideration of a distance from the selection transistor ST to the memory cells MC, the memory cells MC1, MC2, and MC3 where a spike current is expected to occur may be grouped according to a size of a voltage applied to the word line and/or the bit line. The first memory cells MC1 may be spaced apart from the selection transistor ST by a shorter than the second and third memory cells MC2 and MC3, and the second memory cells MC2 may be spaced apart from the selection transistor ST by a shorter distance than the third memory cells MC3.

The conductive layers 410B may include first conductive layers 410B1 respectively connected to the first memory cells MC1, second conductive layers 410B2 respectively connected to the second memory cells MC2, and third conductive layers 410B3 respectively connected to the third memory cells MC3.

Each of the contact structures CS may include the barrier layer 460 and the contact via 470. Here, the barrier layers 460 of the contact structures CS may have substantially the same thickness.

A first group of contact structures G1 may be connected to the first conductive layers 410B1, respectively. For example, a first contact via 470A may be electrically connected to a first one of the first conductive layers 410B1, and a second contact via 470B may be electrically connected to a second one of the first conductive layers 410B1. Here, the first group of contact structures G1 may have substantially the same first width W1. For example, a difference between widths of a pair of the first group of contact structures G1 may be not greater than 5%, 3%, or 1% of an average of the widths. In some embodiments, the first and second contact vias 470A and 470B may have substantially the same width. Here, the contact structures CS1 may have different heights.

A second group of contact structures G2 may be connected to the second conductive layers 410B2, respectively. For example, a third contact via 470C may be electrically connected to a first one of the second conductive layers 410B2, and a fourth contact via 470D may be electrically connected to a second one of the second conductive layers 410B2. Here, the second group of contact structures G2 may have substantially the same second width W2. For example, a difference between widths of a pair of the second group of contact structures G2 may be not greater than 5%, 3%, or 1% of an average of the widths. In some embodiments, the third and fourth contact vias 470C and 470D may have substantially the same width. Here, the second width W2 may be greater than the first width W1. The contact structures CS2 may have different heights.

A third group of contact structures G3 may be connected to the third conductive layers 410B3, respectively. For example, a fifth contact via 470E may be electrically connected to a first one of the third conductive layers 410B3, and a sixth contact via 470F may be electrically connected to a second one of the third conductive layers 410B3. Here, the third group of contact structures G3 may have substantially the same third width W3. In some embodiments, the fifth and sixth contact vias 470E and 470F may have substantially the same width. Here, the third width W3 may be greater than the second width W2. The contact structures CS3 may have different heights.

The first group of contact structures G1 may have substantially the same first width W1. Meanwhile, the contact structures CS1 may have different heights. In this case, the first group of contact structures G1 may have different resistances. Similarly, the second group of contact structures G2 may have different resistances, the third group of contact structures G3 may have different resistances.

According to an embodiment of the present disclosure, the memory cells MC and the conductive layers 410B may be grouped for each level, and thus the contact structures CS may be grouped to first, second, and third groups of contact structures G1, G2, and G3. In this case, by differentially setting a shape of the first, second, and third groups of contact structures G1, G2, and G3, for example, the widths W1, W2, and W3 of the contact structures CS1, CS2, and CS3, for each group, so that a spike current is not generated with respect to one or more specific groups of memory cells MC, and a magnitude of a current applied to each group of memory cells MC1, MC2, and MC3 may be controlled. Through this, the magnitude of the current applied to the group of memory cells MC1, MC2, and MC3 may be kept relatively small, and a spike current may be prevented from occurring in a specific group of memory cells MC.

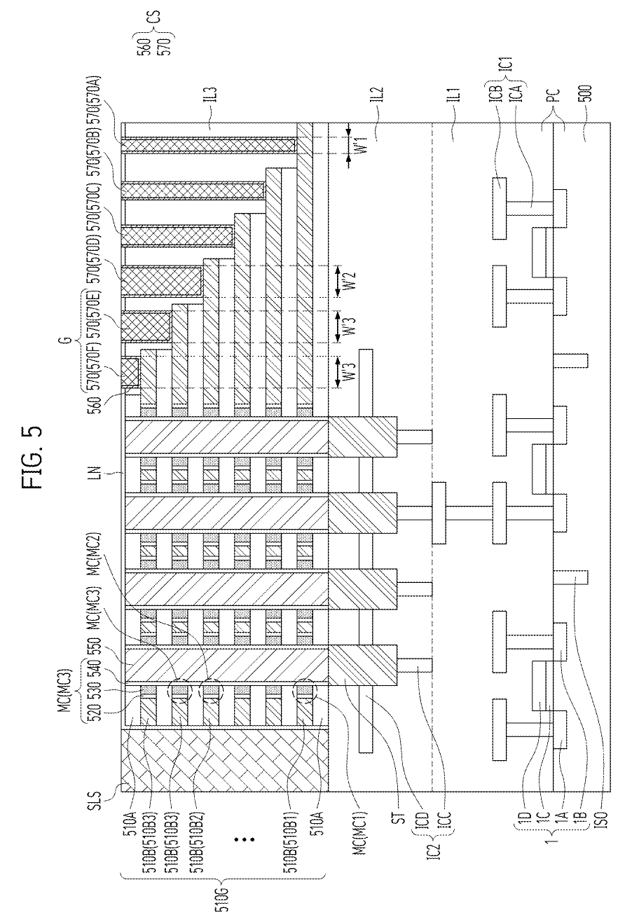

Referring to FIG. 5, the memory cells MC may include a first memory cell MC1 adjacent to the selection transistor ST, a second memory cell MC2 spaced apart relatively farther from the selection transistor ST than the first memory cell MC1, and third memory cells MC3 spaced apart relatively farther from the selection transistor ST than the second memory cell MC2. Here, in consideration of a distance from the selection transistor ST to the memory cells MC, memory cells where a spike current is expected to occur may be classified according to a size of a voltage applied to the word line and/or the bit line. For example, the first memory cell MC1 may be spaced apart from the selection transistor ST by a shorter distance than the second and third memory cells MC2 and MC3, and the second memory cell MC2 may be spaced apart from the selection transistor ST by a shorter distance from the selection transistor ST than the third memory cells MC3. In this case, a spike current may occur in the first and second memory cells MC1 and MC2. Because the third memory cells MC3 are spaced apart from the selection transistor ST by a relatively great distance compared to the first and second memory cells MC1 and MC2, a spike current may not occur.

The conductive layers 510B may include a first conductive layer 510B1 connected to the first memory cell MC1, a second conductive layer 510B2 connected to the second memory cell MC2, and third conductive layers 510B3 respectively connected to the third memory cells MC3.

Each of the contact structures CS may include the barrier layer 560 and the contact via 570. Here, the barrier layers 560 of the contact structures CS may have substantially the same thickness.

A first contact structure may be connected to the first conductive layer 510B1, and may have a first width W’1. A second contact structure may be connected to the second conductive layer 510B2, and may have a second width W’2 different from the first width W’1. Third contact structures may be respectively connected to the third conductive layer 510B3, and may have a third width W’3 different from the first and second widths W’1 and W’2. Here, the first width W’1 may be less than the second width W’2. The second width W’2 may be less than the third width W’3. The third contact structures may be formed as a single group of contact structures.

Because the third memory cells MC3 are spaced apart from the selection transistor ST by a sufficient distance, a spike current may not occur. Because a spike current may occur in the first and second memory cells MC1 and MC2, in order to prevent this, first and second resistances of the first and second contact structures respectively corresponding to the first and second memory cells MC1 and MC2 may be increased. In other words, each of the first and second contact structures may have a resistance greater than a resistance of the third contact structure.

According to an embodiment of the present disclosure, the first contact structure corresponding to the first memory cell MC1 may have the first width W’1 less than the second width W’2 of the second contact structure, and the second contact structure corresponding to the second memory cell MC2 may have the second width W’2 less than the third width W’3 of the third contact structure. In this case, the first contact structure may have a resistance greater than a resistance of the second contact structure. The second contact structure may have the resistance greater than a resistance of the third contact structure. Therefore, by adjusting the widths W’1 and W’2 of the first and second contact structures, a spike current may be prevented from occurring in the first and second memory cells MC1 and MC2. Here, because the third contact structures are electrically connected to the third memory cells MC3 where a spike current does not to occur, the width W’3 of the third contact structures may not be adjusted, and thus the third contact structures may have substantially the same third width W’3.

According to an embodiment (e.g., the structure described above with reference to FIGS. 3A and 3B), a spike current may be prevented from occurring in the memory cells MC by adjusting cross-sectional areas (e.g., S1 and S2 in FIGS. 3A and 3B) where the contact structures CS contact the conductive layers (e.g., 310B in FIG. 3A).

In addition, the memory cells MC may be grouped according to a distance from the selection transistor ST, and thus by grouping the contact structures to a plurality of groups (e.g., first, second, and third groups G1, G2, and G3 in FIG. 4), a spike current may be prevented from occurring in one or more specific groups of memory cells MC.

In addition, according to an embodiment (e.g., the embodiment in FIG. 5) a width of the contact structures CS electrically connected to the memory cells MC disposed relatively farther from the selection transistor ST may not be additionally adjusted, whereas a width of the contact structures CS electrically connected to the memory cells MC disposed relatively adjacently to the selection transistor ST may be adjusted to prevent an occurrence of a spike current in the memory cells MC.

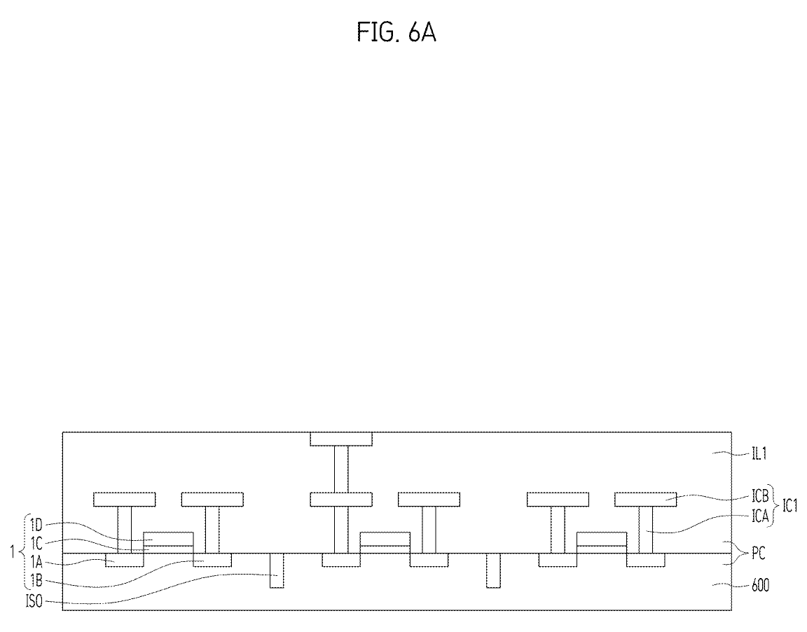

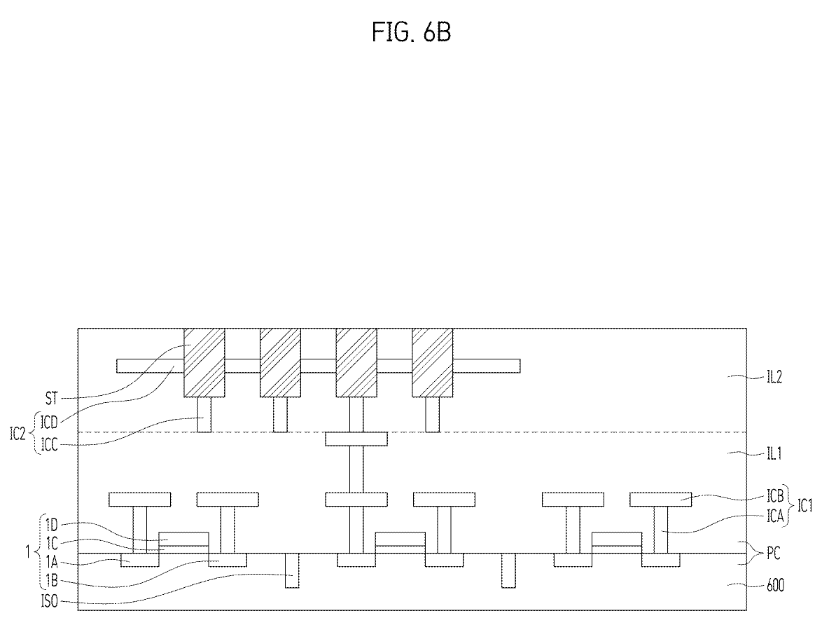

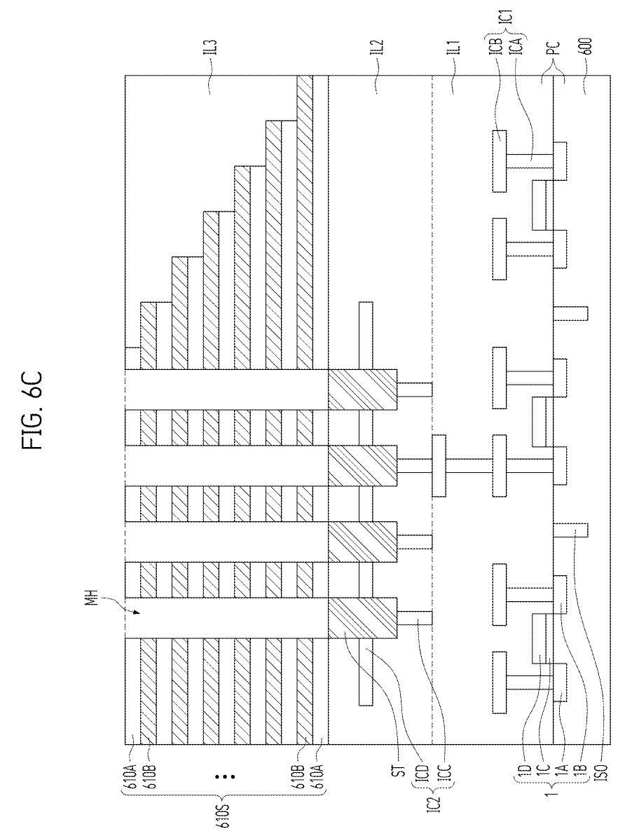

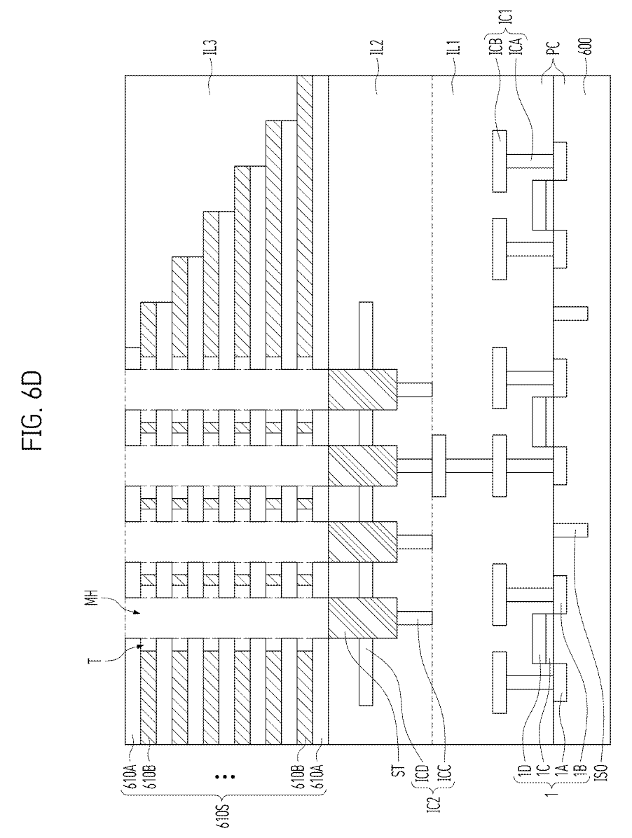

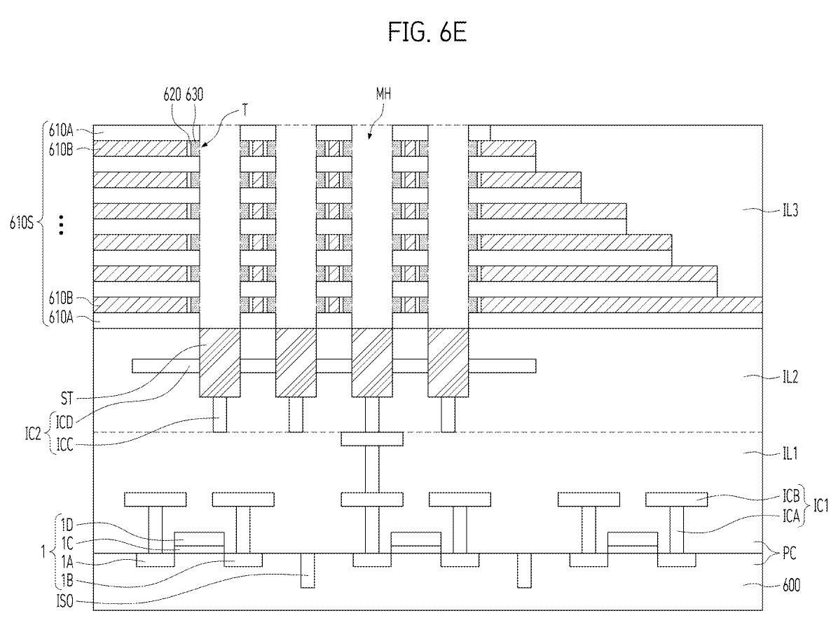

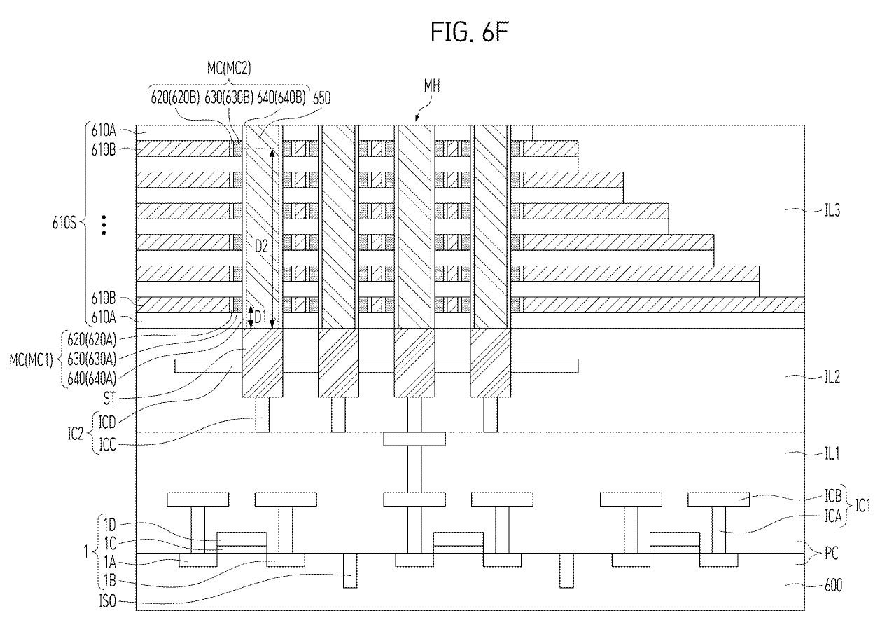

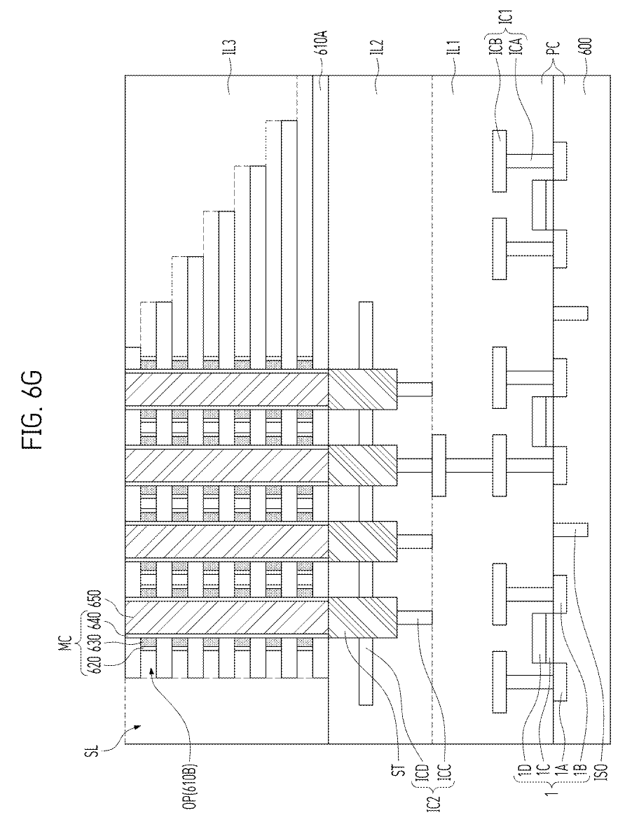

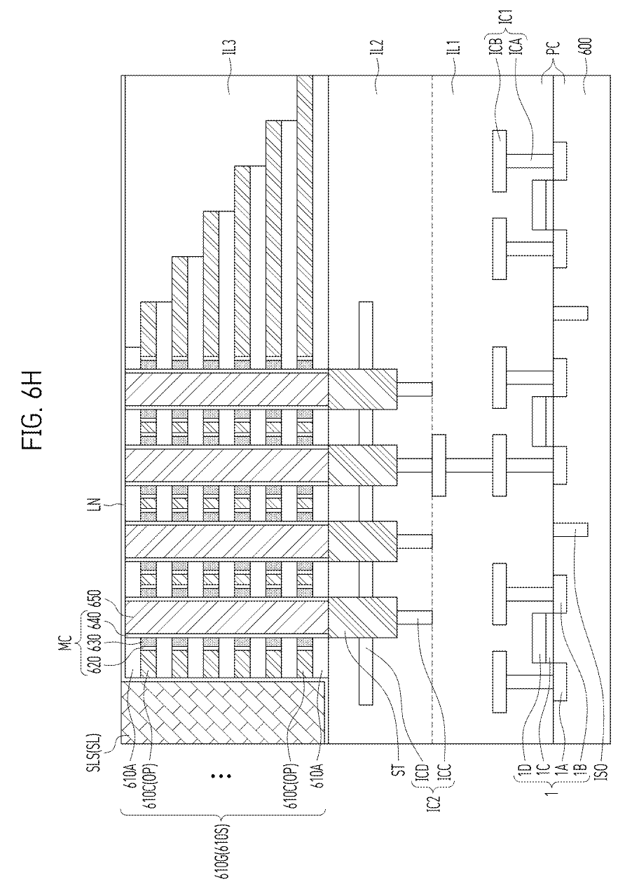

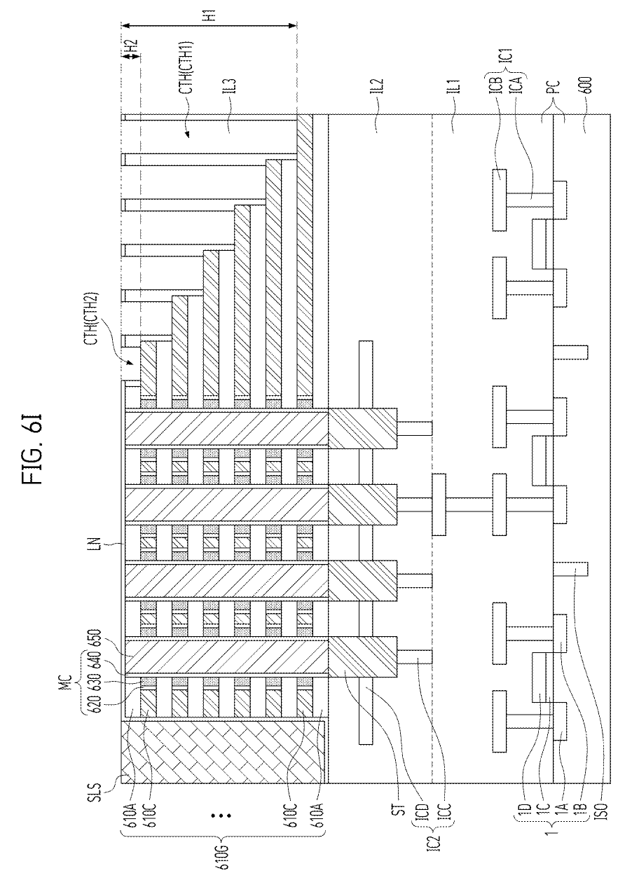

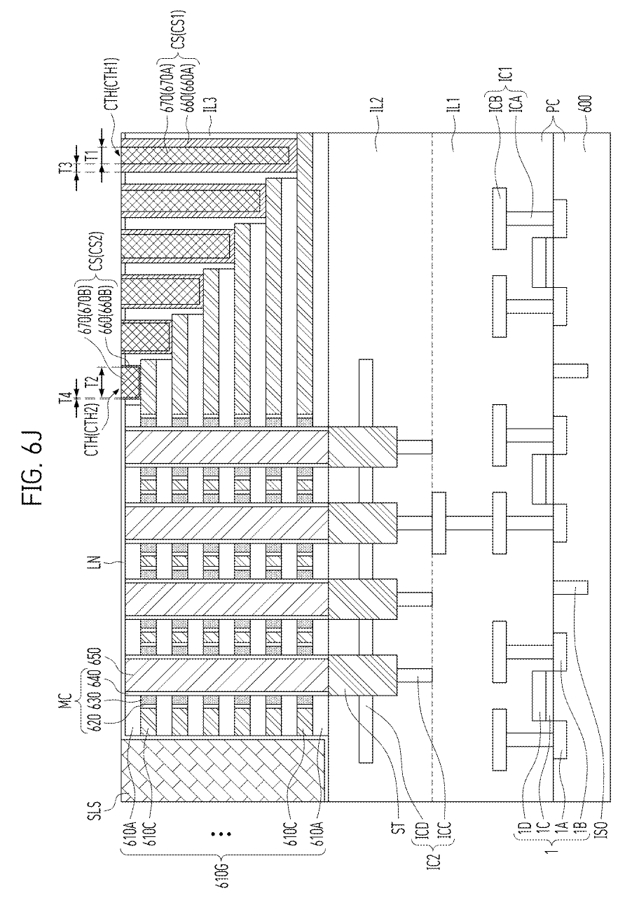

FIGS. 6A, 6B, 6C, 6D, 6E, 6F, 6G, 6H, 6I and 6J, are diagrams illustrating a method of manufacturing a semiconductor device according to an embodiment of the present disclosure. Hereinafter, a content that overlaps the content described above may be omitted for the interest of brevity.

Referring to FIG. 6A, a peripheral circuit PC may be formed on a substrate 600. The peripheral circuit PC may include a transistor 1 and the like. The transistor 1 may include junctions 1A and 1B, a gate insulating layer 1C, and a gate electrode 1D. An element isolation layer ISO may be formed in the substrate 600, an active region may be formed by the element isolation layer ISO, and the transistor 1 may be formed in the active region.

Subsequently, a first interconnection structure IC1 may be formed on the peripheral circuit PC. The first interconnection structure IC1 may be formed in a first interlayer insulating layer IL1. Here, the first interlayer insulating layer IL1 may be formed on the substrate 600. The first interconnection structure IC1 may include first vias ICA and first lines ICB. At least one of the first vias ICA may be connected to the peripheral circuit PC. The first lines ICB may interconnect the first vias ICA. The first interconnection structure IC1 may include a conductive material such as tungsten, and the first interlayer insulating layer IL1 may include an insulating material such as an oxide.

Referring to FIG. 6B, a second interconnection structure IC2 may be formed on the first interconnection structure IC1. Here, the second interconnection structure IC2 may be formed in a second interlayer insulating layer IL2. The second interlayer insulating layer IL2 may be formed on the first interlayer insulating layer IL1. The second interconnection structure IC2 may include second lines ICC and third lines ICD. One of the second lines ICC may be connected to the first line ICB. For reference, the first line ICB and the second line ICC may be connected through a connection via (not shown). The third line ICD may be electrically connected to the second line ICC through a selection transistor ST.

The selection transistor ST may be formed on the substrate 600. For example, the selection transistor ST may be formed on the first interconnection structure IC1. The selection transistor ST may be formed to be connected to the second line ICC by extending through the third line ICD.

Referring to FIG. 6C, a sacrificial stack 610S may be formed by alternately stacking first material layers 610A and second material layers 610B on the selection transistor ST. For example, the first material layers 610A and second material layers 610B are alternately stacked to form a step structure. Here, the sacrificial stack 610S may include a step structure exposing upper surfaces of the second material layers 610B. The first material layers 610A may include an insulating material such as an oxide, and the second material layers 610B may include a sacrificial material such as a nitride.

Subsequently, a third interlayer insulating layer IL3 may be formed on the step structure. For example, the third interlayer insulating layer IL3 may be formed to cover upper surfaces of the second material layers 610B exposed by the step structure. Here, the third interlayer insulating layer IL3 may include an insulating material such as an oxide. In other embodiments, the sacrificial stack 610S may not include a step structure. In this case, a process of forming the third interlayer insulating layer IL3 may be omitted.

Subsequently, memory holes MH extending through the sacrificial stack 610S and exposing the second material layers 610B may be formed. Here, sidewalls of the second material layers 610B may be exposed through the memory holes MH. In addition, the selection transistors ST may be exposed through the memory holes MH.

Referring to FIGS. 6D -6F, memory cells MC may be formed in the sacrificial stack 610S. First, trenches T may be formed by partially etching the second material layers 610B through the memory holes MH. Subsequently, first electrode patterns 620 may be formed in the trenches T, respectively. For example, a first electrode layer may be conformally formed along a profile of the memory holes MH and the trenches T. Subsequently, the first electrode layer may be etched so that the first electrode patterns 620 are formed at a level corresponding to the second material layers 610B. Specifically, the first electrode layer may be etched so as make upper and lower surfaces of the first electrode pattern 620 substantially coplanar with upper and lower surfaces of a corresponding (e.g., contacting) one of the second material layers 610B, respectively. For example, a level difference between the upper surface of the first electrode pattern 620 and the upper surface of the second material layer 610B may not be greater than 5%, 3%, or 1% of an average of thicknesses of the first electrode pattern 620 and the second material layer 610B. Subsequently, variable resistance patterns 630 may be formed on the first electrode patterns 620, respectively. For example, a variable resistance layer may be formed in the memory holes MH to fill the trenches T. Subsequently, the variable resistance patterns 630 may be formed in the trenches T, respectively, by removing portions of the variable resistance layer formed in the memory holes MH while retaining other portions of the variable resistance layer formed in the trenches T.

Subsequently, second electrode patterns 640 may be formed in the memory holes MH. For example, a second electrode layer may be conformally formed in the memory holes MH. Subsequently, the second electrode patterns 640 may be formed by etching a portion of the second electrode layer so that the selection transistor (e.g., an upper surface of the selection transistor) ST is exposed. Accordingly, the memory cells MC including the first electrode patterns 620, the variable resistance patterns 630, and the second electrode pattern 640 may be included.

Subsequently, conductive plugs 650 extending through the memory cells MC may be formed, respectively. For example, the conductive plugs 650 may be formed in the memory holes MH, respectively.

The memory cells MC may include a first memory cell MC1 and a second memory cell MC2 on (or over) the first memory cell MC1. Here, the first memory cell MC1 may be spaced apart from the selection transistor ST by a first distance D1, and the second memory cell MC2 may be spaced apart from the selection transistor ST by a second distance D2 greater than the first distance D1.

Because the first memory cell MC1 has the first distance D1 shorter than the distance D2 of the second memory cell MC2, in other words, because a length of a first portion of the conductive plug 650 from the selection transistor ST to the first memory cell MC1 is shorter than a length of a second portion of the conductive plug 650 from the selection transistor ST to the second memory cell MC2, when a current flows from the selection transistor ST through the conductive plug 650, a relatively high spike current may momentarily flow to the first memory cell MC1. In this case, the first memory cell MC1 may be damaged. Therefore, according to an embodiment of the present disclosure, a relatively small resistance of the first memory cell MC1 may be compensated for to substantially prevent or reduce a flow of the spike current to the first memory cell MC1.

Referring to FIGS. 6G and 6H, a slit SL extending through the sacrificial stack 610S may be formed. Subsequently, openings OP may be formed by removing the second material layers 610B through the slit SL. Subsequently, conductive layers 610C may be formed in the openings OP, respectively. Accordingly, an electrode stack 610G including the first material layers 610A and the conductive layers 610C alternately stacked may be formed. For reference, the conductive layers 610C may include a first conductive layer connected to the first memory cell (e.g., MC1 in FIG. 1A) and a second conductive layer connected to the second memory cell (e.g., MC2 in FIG. 1A).

In other embodiments, when the second material layers 610B include a conductive material, a process of replacing the second material layers 610B with the third material layers 610C may be omitted, thereby simplifying a manufacturing process of a semiconductor device. In this case, the sacrificial stack 610S may be used as the electrode stack 610G.

Subsequently, a liner layer LN may be formed on the slit SL and the electrode stack 610G. For example, the liner layer LN may be formed to extend along a side surface and a lower surface of the slit SL and an upper surface of the electrode stack 610G. The liner layer LN may include an insulating material such as an oxide or a nitride.

Subsequently, a slit structure SLS may be formed in the slit SL. For example, the slit structure SLS may be formed by forming at least one of an insulating material, a conductive material, or a semiconductor material in the slit SL.

Referring to FIG. 6I, contact holes CTH of different heights respectively exposing the conductive layers 610C by extending through the third interlayer insulating layer IL3 may be formed. The contact holes CTH may include a first contact hole CTH1 having a first height H1 and a second contact hole CTH2 having a second height H2 different from the first height H1. Here, the first height H1 may be greater than the second height H2. Here, widths of the contact holes CTH may be substantially the same. For example, a difference between widths of a pair of the contact holes CTH may be not greater than 5%, 3%, or 1% of an average of the widths. In other embodiments, when the sacrificial stack 610S does not include a step structure, the contact holes CTH may be formed to expose the conductive layers 610C, respectively, through the sacrificial stack 610S.

Referring to FIG. 6J, barrier layers 660 may be formed in different thicknesses in the contact holes CTH. In some embodiments, at least two of the barrier layers 660 may have different thicknesses. For example, a first barrier layer 660A may be formed in a third thickness T3 in the first contact hole CTH1, and a second barrier layer 660B may be formed in a fourth thickness T4 less than the third thickness T3 in the second contact hole CTH2. Here, the barrier layers 660 may be conformally formed to fill corresponding (e.g., contacting) portions of the contact holes CTH.

In other embodiments, when the sacrificial stack 610S does not include a step structure, insulating spacers may be formed prior to forming the barrier layers 660. Here, the insulating spacers may insulate a contact structure CS from remaining conductive layers 610C except for the conductive layer 610C connected to the contact structure CS.

Subsequently, contact vias 670 may be formed to fill the contact holes CTH. In some embodiments, at least two of the contact vias 670 may be formed in different widths in the barrier layers 660. For example, a first contact via 670A may be formed in a first width T1 in the first barrier layer 660A, and a second contact via 670B may be formed in a second width T2 greater than the first width T1 in the second barrier layer 660B.

The contact vias 670 may include the first contact via 670A electrically connected to the first conductive layer and the second contact via 670B electrically connected to the second conductive layer. The barrier layers 660 may include the first barrier layer 660A covering the first contact via 670A and the second barrier layer 660B covering the second contact via 670B.

The contact vias 670 may have a first resistivity, and the barrier layers 660 may have a second resistivity greater than the first resistivity. The contact vias 670 may include a metal material, and the barrier layers 660 may include a metal nitride. For example, the contact vias 670 may include tungsten, and the barrier layers 660 may include tungsten nitride.

The contact structures CS may include the contact vias 670 and the barrier layers 660. For example, the first contact structure CS1 may include the first contact via 670A and the first barrier layer 660A, and may have a first resistance. The second contact structure CS2 may include the second contact via 670B and the second barrier layer 660B, and may have a second resistance.

The first contact structure CS1 may have a first height H1 greater than a second height H2 of the second contact structure CS2. In addition, the first contact structure CS1 may include the first contact via 670A having a width less than a width of the second contact via 670B of the second contact structure CS2, and may include the first barrier layer 660A having a thickness greater than a thickness of the second barrier layer 660B of the second contact structure CS2. Each of the first and second contact vias 670A and 670B may have a resistivity less than that of each of the first and second barrier layers 660A and 660B. Therefore, the first resistance of the first contact structure CS1 may be greater than the second resistance of the second contact structure CS2.

In other words, the first resistance of the first contact structure CS1 corresponding to the first memory cell MC1 formed adjacent to the selection transistor ST may be greater than the second resistance of the second contact structure CS2 corresponding to the second memory cell MC2 disposed relatively farther from the selection transistor ST. Therefore, the first contact structure CS1 may prevent the first memory cell MC1 from being damaged by compensating for the relatively small resistance between the first memory cell MC1 and the selection transistor ST.

According to the manufacturing method described above, the contact holes CTH having different heights may be formed. Subsequently, the barrier layers 660 may be formed in different thicknesses in the contact holes CTH. Subsequently, the contact vias 670 may be formed in different widths in the barrier layers 660. In other words, by adjusting the thickness of the barrier layers 660 formed in the contact holes CTH and the widths of the contact vias 670, the resistance of the contact structure may be controlled, thereby compensating for a relatively small resistance associated with the memory cells MC disposed adjacent to the selection transistor ST. Therefore, the memory cells MC formed adjacent to the selection transistor ST may be prevented from being damaged.

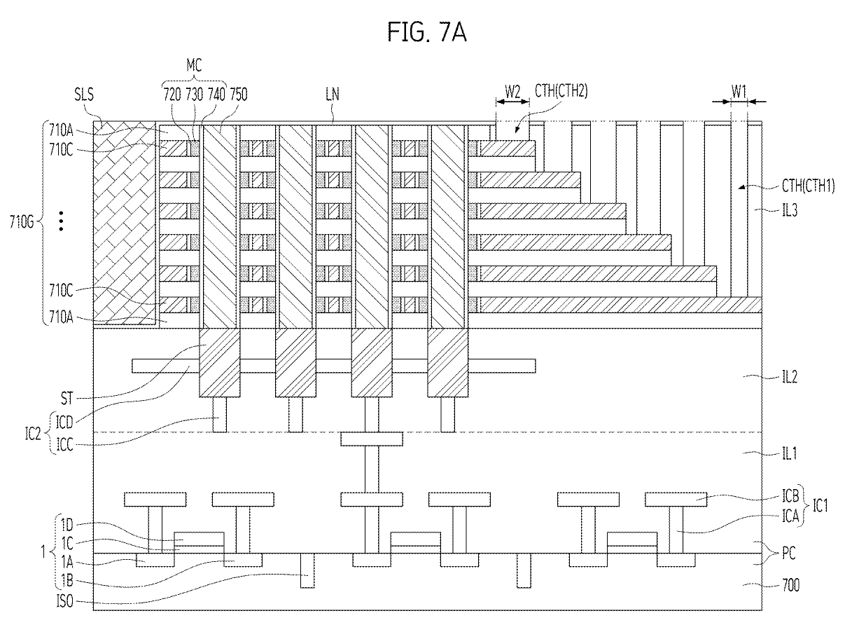

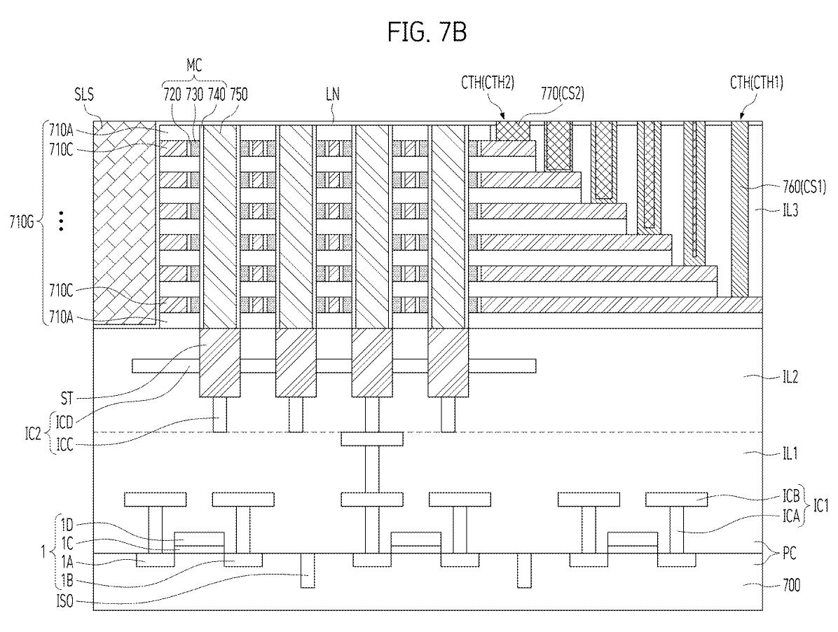

FIGS. 7A and 7B are diagrams illustrating a method of manufacturing a semiconductor device according to an embodiment of the present disclosure. Hereinafter, a content that overlaps the content described above may be omitted for the interest of brevity.

Referring to FIG. 7A, the semiconductor device may be formed in a method similar to that of FIGS. 6A - 6I. First, a peripheral circuit PC may be formed on a substrate 700. The peripheral circuit PC may include a transistor 1 and the like. The transistor 1 may include junctions 1A and 1B, a gate insulating layer 1C, and a gate electrode 1D. An element isolation layer ISO may be formed in the substrate 700, an active region may be formed by the element isolation layer ISO, and the transistor 1 may be formed in the active region.

Subsequently, a first interconnection structure IC1 may be formed on the peripheral circuit PC. The first interconnection structure IC1 may be formed in a first interlayer insulating layer IL1. Here, the first interlayer insulating layer IL1 may be formed on the substrate 700. The first interconnection structure IC1 may include first vias ICA and first lines ICB.

Subsequently, a second interconnection structure IC2 may be formed on the first interconnection structure IC1. Here, the second interconnection structure IC2 may be formed in a second interlayer insulating layer IL2. The second interlayer insulating layer IL2 may be formed on the first interlayer insulating layer IL1. The second interconnection structure IC2 may include second lines ICC and third lines ICD.

Subsequently, a selection transistor ST may be formed on the first interconnection structure IC1. The selection transistor ST may be formed to be connected to the second line ICC by extending through the third line ICD.

An electrode stack 710G including first material layers 710A and conductive layers 710C alternately stacked on the selection transistor ST may be formed. For example, the first material layers 710A and conductive layers 710C are alternately stacked to form a step structure. Here, the electrode stack 710G may have a step structure exposing upper surfaces of the conductive layers 710C, and the upper surface of the conductive layers 710C exposed by the step structure may be covered by a third interlayer insulating layer IL3.

Memory cells MC and conductive plugs 750 may be formed in the electrode stack 710G. Here, the memory cells MC may include first electrode patterns 720, variable resistance patterns 730, and a second electrode pattern 740. A slit structure SLS extending through the electrode stack 710G may be formed. A liner layer LN may be formed between the slit structure SLS and the electrode stack 710G.

Subsequently, contact holes CTH extending through the third interlayer insulating layer IL3 and exposing the conductive layers 710, respectively, may be formed. In some embodiments, at least two of the contact holes CTH may have different heights. For example, contact holes CTH may include a first contact hole CTH1 having a relatively large height and a second contact hole CTH2 having a relatively small height. Here, the first contact hole CTH1 may have a first width W1, and the second contact hole CTH2 may have a second width W2 greater than the first width W1.

For reference, although this drawing illustrates a case where all widths of the contact holes CTH are different, all widths of the contact holes CTH may not be formed differently. As an example, the contact holes may be grouped in consideration of a distance of the memory cells spaced from the selection transistor, and the widths of the contact holes may be formed differently according to a group of the contact holes. As another example, in a case of memory cells in which a spike current is not expected to occur among the memory cells spaced apart from the selection transistor, because widths of contact holes corresponding thereto may not be adjusted, the widths of the contact holes may be substantially the same, and in a case of memory cells in which a spike current is expected to occur, because widths of contact holes corresponding thereto may be adjusted, the widths of the contact holes may be formed differently.

Referring to FIG. 7B, contact structures may be formed in the contact holes CTH, respectively. Here, the contact structure may include at least one of a barrier layer 760 or a contact via 770. For example, a first contact structure CS1 formed in the first contact hole CTH1 may consist of the barrier layer 760. As another example, a second contact structure CS2 formed in the second contact hole CTH2 may consist of the contact via 770.

In other words, the first contact structure CS1 may have a height larger than a height of the second contact structure CS2, and the first contact structure CS1 may have the first width W1 less than the second width W2 of the second contact structure CS2. In addition, the first contact structure CS1 may include the barrier layer 760 of which a resistivity is relatively great, and the second contact structure CS2 may include the contact via 770 of which a resistivity is relatively small. Therefore, a resistance of the first contact structure CS1 may be greater than a resistance of the second contact structure CS2.

According to an embodiment of the present disclosure, the first contact structure CS1 may have the resistance greater than the resistance of the second contact structure CS2. In this case, the first contact structure CS1 may prevent or minimize damage to the memory cell MC disposed relatively adjacent to the selection transistor ST due to a spike current.

For reference, although this drawing illustrates a case where the first and second widths W1 and W2 of the first and second contact holes CTH1 and CTH2 are constant from an upper portion to a lower portion, the first and second contact holes CTH1 and CTH2 may have a cross-section of a taper shape. For example, the widths of the first and second contact holes CTH1 and CTH2 may be decreased from the upper portion to the lower portion. In this case, the widths of the first and second contact holes CTH1 and CTH2 may be different, and cross-sectional areas of the conductive layers 710C exposed by the first and second contact holes CTH1 and CTH2 may be different.

In addition, although this drawing illustrates a case where the first contact structure CS1 does not include the contact via 770 and the second contact structure CS2 does not include the barrier layer 760, but embodiments of the present disclosure are not limited thereto. For example, the first contact structure CS1 may include the contact via 770, and the second contact structure CS2 may include the barrier layer 760 covering the contact via 770.

In addition, although this drawing illustrates a case where the barrier layer 760 and the contact via 770 have different thicknesses and widths, the thicknesses of the barrier layer 760 and the widths of the contact via 770 are not limited thereto. For example, barrier layers of substantially the same thickness may be formed in the contact holes, and contact vias of different widths may be formed in the barrier layers.

According to the manufacturing method described above, the contact holes CTH having different heights may be formed. Here, the contact holes CTH may have different widths. For example, the width of the contact holes CTH having a relatively great height may be less than the width of the contact holes CTH having a relatively small height. Subsequently, the contact structures may be formed in the contact holes CTH. Through this, a relatively small resistance associated with the memory cells MC disposed adjacent to the selection transistor ST may be compensated for, and such memory cells MC may be prevented from being damaged.

Although some embodiments according to the technical spirit of the present disclosure have been described with reference to the accompanying drawings, various embodiments of the present disclosure are not limited to the above-described embodiments. Various forms of substitution, modification, and change of the embodiments may be possible by those skilled in the art to which the present disclosure belongs, and these also belong to embodiments of the present disclosure.

What is claimed is:

1. A semiconductor device comprising:
an electrode stack including conductive layers and insulating layers that are alternately stacked to form a step structure;
a conductive plug extending through the electrode stack;
memory cells disposed between the conductive layers and the conductive plug;
an interlayer insulating layer disposed on the step structure;
contact vias extending through the interlayer insulating layer and electrically connected to the conductive layers, respectively, and at least two of the contact vias having different widths; and
barrier layers covering the contact vias, respectively, and at least two of the barrier layers having different thicknesses.

2. The semiconductor device of claim 1, wherein the memory cells include a first memory cell and a second memory cell over the first memory cell,
wherein the conductive layers include a first conductive layer connected to the first memory cell and a second conductive layer connected to the second memory cell,
wherein the contact vias include a first contact via electrically connected to the first conductive layer and a second contact via electrically connected to the second conductive layer,
wherein the barrier layers include a first barrier layer covering the first contact via and a second barrier layer covering the second contact via,
wherein the first contact via has a first width, and the second contact via has a second width greater than the first width, and
wherein the first barrier layer has a third thickness, and the second barrier layer has a fourth thickness less than the third thickness.

3. The semiconductor device of claim 2, further comprising:
a selection transistor disposed under the electrode stack, and connected to the conductive plug.

4. The semiconductor device of claim 3, wherein the first memory cell is spaced apart from the selection transistor by a first distance, and the second memory cell is spaced apart from the selection transistor by a second distance greater than the first distance, and
wherein a first contact structure includes the first contact via and the first barrier layer and has a first resistance, and a second contact structure includes the second contact via and the second barrier layer and has a second resistance less than the first resistance.

5. The semiconductor device of claim 4, wherein a width of the first contact structure is substantially the same as a width of the second contact structure.

6. The semiconductor device of claim 4, wherein a width of the first contact structure is less than a width of the second contact structure.

7. The semiconductor device of claim 4, wherein the first contact structure has a first height, and
wherein the second contact structure has a second height less than the first height.

8. The semiconductor device of claim 1, wherein the contact vias each have a first resistivity, and the barrier layers each have a second resistivity greater than the first resistivity.

9. The semiconductor device of claim 8, wherein the contact vias each include a metal material, and the barrier layers each include a metal nitride.

10. The semiconductor device of claim 9, wherein the contact vias each include tungsten, and the barrier layers each include tungsten nitride.

11. The semiconductor device of claim 1, wherein each of the memory cells comprises:
a first electrode pattern disposed at a substantially same level as a corresponding one of the conductive layers;
a second electrode pattern covering a sidewall of the conductive plug; and
a variable resistance pattern disposed between the first electrode pattern and the second electrode pattern.

12. A semiconductor device comprising:
an electrode stack including a first conductive layer and a second conductive layer over the first conductive layer, the first conductive layer extending laterally beyond the second conductive layer to form a step structure;
a conductive plug extending through the electrode stack;
a selection transistor disposed under the electrode stack and connected to the conductive plug;
a first memory cell disposed between the first conductive layer and the conductive plug and spaced apart from the selection transistor by a first distance;
a second memory cell disposed between the second conductive layer and the conductive plug and spaced apart from the selection transistor by a second distance greater than the first distance;
an interlayer insulating layer disposed on the step structure;
a first contact structure extending through the interlayer insulating layer to be connected to the first conductive layer, and having a first resistance; and
a second contact structure extending through the interlayer insulating layer to be connected to the second conductive layer, and having a second resistance less than the first resistance.

13. The semiconductor device of claim 12, wherein the first contact structure includes a first contact via and a first barrier layer covering the first contact via,
wherein the second contact structure includes a second contact via and a second barrier layer covering the second contact via,
wherein the first contact via has a first width, and the second contact via has a second width greater than the first width, and
wherein the first barrier layer has a third thickness, and the second barrier layer has a fourth thickness less than the third thickness.

14. The semiconductor device of claim 13, wherein the first contact via and the second contact via each have a first resistivity, and the first barrier layer and the second barrier layer each have a second resistivity greater than the first resistivity.

15. The semiconductor device of claim 12, wherein a width of the first contact structure is substantially the same as a width of the second contact structure.

16. The semiconductor device of claim 12, wherein a width of the first contact structure is less than a width of the second contact structure.

17. The semiconductor device of claim 12, wherein the first contact structure has a first height, and the second contact structure has a second height less than the first height.

18. A semiconductor device comprising:
an electrode stack including conductive layers and insulating layers that are alternately stacked;
a conductive plug extending through the electrode stack;
a selection transistor disposed under the electrode stack and connected to the conductive plug;
memory cells disposed between the conductive layers and the conductive plug; and
contact structures connected to the conductive layers, respectively.

19. The semiconductor device of claim 18, wherein the contact structures comprise:
contact vias electrically connected to the conductive layers, respectively, and having different widths; and
barrier layers covering the contact vias, respectively, and having different thicknesses.

20. The semiconductor device of claim 18, wherein the conductive layers include a first conductive layer and a second conductive layer over the first conductive layer, and
wherein the contact structures include a first contact structure connected to the first conductive layer and having a first resistance, and a second contact structure connected to the second conductive layer and having a second resistance less than the first resistance.

21. The semiconductor device of claim 18, wherein the conductive layers include a first conductive layer and a second conductive layer over the first conductive layer,
wherein the memory cells include a first memory cell disposed between the first conductive layer and the conductive plug and spaced apart from the selection transistor by a first distance, and a second memory cell disposed between the second conductive layer and the conductive plug and spaced apart from the selection transistor by a second distance greater than the first distance, and
wherein the contact structures include a first contact structure connected to the first conductive layer and having a first area that contacts the first conductive layer, and a second contact structure connected to the second conductive layer and having a second area that contacts the second conductive layer and is greater than the first area.

22. The semiconductor device of claim 21, wherein the first contact structure includes a first contact via having a first width and a first barrier layer covering the first contact via, and
wherein the second contact structure includes a second contact via having a second width greater than the first width and a second barrier layer covering the second contact via.

23. The semiconductor device of claim 22, wherein a thickness of the first barrier layer and a thickness of the second barrier layer are substantially the same.

24. The semiconductor device of claim 18, wherein the conductive layers include first conductive layers and second conductive layers over the first conductive layers,
wherein the memory cells include first memory cells disposed between the first conductive layers and the conductive plug, and second memory cells disposed between the second conductive layers and the conductive plug,
wherein the contact structures include a first group of contact structures respectively connected to the first conductive layers and each having a first width, and a second group of contact structures respectively connected to the second conductive layers and each having a second width greater than the first width.

25. The semiconductor device of claim 24, wherein the first group of contact structures have substantially the same width, and
wherein the second group of contact structures have substantially the same width.

26. The semiconductor device of claim 18, wherein the conductive layers include a first conductive layer, a second conductive layer over the first conductive layer, and third conductive layers over the second conductive layer,
wherein the memory cells include a first memory cell disposed between the first conductive layer and the conductive plug, a second memory cell disposed between the second conductive layer and the conductive plug, and third memory cells disposed between the third conductive layers and the conductive plug, and
wherein the contact structures include a first contact structure connected to the first conductive layer and having a first width, a second contact structure connected to the second conductive layer and having a second width greater than the first width, and a group of third contact structures respectively connected to the third conductive layers and each having a third width greater than the second width.

27. The semiconductor device of claim 26, wherein the first contact structure has a first resistance,
wherein the second contact structure has a second resistance less than the first resistance, and
wherein the group of third contact structures each have a third resistance less than the second resistance.
